(19) United States
(12) Patent Application Publication
(10) Pub. No.: US 2010/0120241 A1
(43) Pub. Date: May 13, 2010

(54) METHOD OF MANUFACTURING SEMICONDUCTOR DEVICE

(75) Inventor: Shigeru SAITO, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki (JP)

(21) Appl. No.: 12/579,137

(22) Filed: Oct. 14, 2009

(30) Foreign Application Priority Data
Nov. 11, 2008 (JP) 2008-288522

(51) Int. Cl. H01L 21/768

(52) U.S. Cl. 438/618; 257/E21.575

(57) ABSTRACT

Provided is a method of manufacturing a semiconductor device including an integrated circuit having a plurality of semiconductor elements which are formed on a semiconductor substrate and electrically connected through a line, the method including: forming a conducting path to be connected to the semiconductor elements in a similar manner as the line is to be connected thereto; etching the semiconductor elements in a state where the semiconductor elements are electrically connected via the conducting path; and forming the line to be connected to the semiconductor elements in a similar manner as the conducting path is connected thereto.

### BACKGROUND

1. Field of the Invention

The present invention relates to a method of manufacturing a semiconductor device. In particular, the present invention relates to a method of manufacturing a semiconductor device including an etching process for an integrated circuit in which a plurality of semiconductor elements formed on a semiconductor substrate are electrically connected through a line.

2. Description of Related Art

In manufacturing semiconductor devices including a heterojunction bipolar transistor (HBT), a hot electron transistor (HET), a field effect transistor (FET) or the like, an etching process is generally carried out in the state where semiconductor elements such as transistors and resistors are not electrically connected to each other. This approach is adopted to prevent unnecessary electrical connection in a circuit and to be able to observe characteristics of elements individually. Accordingly, the etching process is carried out after devices are isolated from each other (isolation). Then, after the etching process is finished, those circuit elements are connected through a conductor (line pattern), thereby obtaining an integrated circuit having desired functions.

In this regard, however, it is widely known that when the etching process is carried out in the state where the devices are isolated from each other, the etching uniformity is deteriorated. The reason for this seems that electrons generated in the etching process stay in each isolated region and the isolated elements are individually affected by the stationary electrons. As a result, the elements have different etching rates, and the characteristics of the elements vary. Such a phenomenon is noticeable especially when the regions to be etched have various sizes.

In the method of performing etching in the state where all the circuit elements provided in the integrated circuit are isolated from each other, the characteristics of the elements are likely to vary as described above. Meanwhile, in the case of manufacturing semiconductor devices such as HBTs, HETs, and FETs, it is often necessary to etch a semiconductor layer to a precisely controlled depth, as in the case of recess etching for FETs and etching for exposing the base of HBTs, for example. Accordingly, in the semiconductor device which requires precise etching, the etching process is conventionally performed by electrically connecting part of the elements through a semiconductor (diffusion line) having a conductivity (which is hereinafter referred as a conductive path), without completely isolating the elements.

This conventional method is effective for circuits in which part of elements are connected to the same potential, e.g., a ground, for example. In the case of an amplifier in which all the sources of a plurality of transistors are grounded, for example, the final form of the amplifier obtained in the state where the sources of the transistors are connected through conducting paths have no influence on the functions of the integrated circuit. This is because all the sources of the transistors have the same potential in the circuit. On the other hand, in the case of a circuit in which all the sources of a plurality of transistors do not have the same potential, the formation of conducting paths leading from all the transistors to the ground may cause a problem.

The problem will be described with reference to FIGS. 4 and 5. FIG. 4 is a schematic diagram showing an example of a semiconductor device formed by using the conventional method of manufacturing a semiconductor device. FIG. 5 is a circuit diagram of the semiconductor device shown in FIG. 4. FIG. 4 illustrates the final form of the semiconductor device which includes a circuit having transistors whose sources do not have the same potential, and which is manufactured using the conventional method. In this case, a description is given of a semiconductor device including an integrated circuit having an amplifying transistor FET2 whose source is grounded and a bias circuit for supplying a bias to the amplifying transistor FET2, as an example of the circuit having transistors whose sources do not have the same potential.

Specifically, in the bias circuit, resistors R1 and R2 for supplying a bias to a bias transistor FET1 is connected, through a line 31. The gate of the bias transistor FET1 is connected between the resistors R1 and R2. The bias transistor FET1 has a drain connected to a resistor R3 through a line 39, and a source connected to a resistor R4 for feedback control of the bias circuit, through a line 32. The source of the bias transistor FET1 is connected to the gate of the amplifying transistor FET2 through the line 32, a line 36, a resistor R5, and a line 37. The resistor R1 is connected to a ground plane 40 through a line 38, and the resistor R4 is connected to the ground plane 40 through a line 33. Note that the source of the amplifying transistor FET2 is connected to a line 35 through a line 34, and is grounded via a through-hole 41 which is formed in the line 35.

A description will be given of a case of manufacturing the semiconductor device including the circuit in which the source of the bias transistor FET1 and the source of the amplifying transistor FET2 do not have the same potential as described above by using the conventional method. Prior to the etching process, conducting paths leading from all the transistors to the ground are formed. Specifically, as shown in FIG. 4, a conducting path 21 leading from the bias transistor FET1 to the ground plane 40, and a conducting path 22 leading from the amplifying transistor FET2 to the ground plane 40 are formed. As a result, the bias transistor FET1 is grounded via the conducting path 21, and the amplifying transistor FET2 is grounded via the conducting path 22. Then, etching is carried out in the state where the sources of all the transistors are grounded via the conducting paths. After the etching process, the lines 31 to 39 are formed in the subsequent process, thereby completing the semiconductor device.

The final form of the semiconductor device thus manufactured is shown in FIG. 4. Specifically, the conducting path 21 leading to the ground plane 40 is still connected to the source of the bias transistor FET1. Accordingly, as shown in FIG. 5, the source of the bias transistor FET1 is connected not only to the resistor R4 which is originally designed, but also to another resistor R21 which is generated by the conducting path 21. This varies an initially-set circuit constant, with the result that a desired operation cannot be obtained.

In other words, the conventional method can realize uniform etching, but has a problem that it can be applied only to particular circuits as the conducting paths which are formed to achieve uniform etching may have an influence on the circuit. As described above, the application of the conventional method is limited to the production of circuits in which part of elements are connected to the same potential, for example.

A technique for solving the above-mentioned problem is disclosed in Japanese Unexamined Patent Application Publication No. 10-163223. FIGS. 6A, 6B, 7A, and 7B are diagrams each illustrating a method of manufacturing a semiconductor device according to Prior Art disclosed in Japanese Unexamined Patent Application Publication No. 10-163223. FIG. 6A is a sectional perspective view schematically showing a subcell of the semiconductor device obtained after an etching process. FIG. 6B is a cross-sectional view showing the semiconductor device obtained after the etching process. FIG. 7A is a sectional perspective view schematically showing a subcell of the semiconductor device obtained after a conducting path is disrupted. FIG. 7B is a cross-sectional view showing the semiconductor device obtained after the conducting path is disrupted.

In Prior Art disclosed in Japanese Unexamined Patent Application Publication No. 10-163223, an ion implantation is first carried out for a laminated body which is formed by depositing a predetermined semiconductor layer on a semi-insulating semiconductor substrate. Consequently, a predetermined region of the laminated body is changed into an insulator 51, as indicated by “+” in FIG. 6A. As a result, a conducting path 52 which electrically connects the left end and the right end of FIG. 6A is left on the laminated body. Accordingly, subcells (not shown) which exist on both ends of the conducting path 52 are electrically connected to each other. That is, in the laminated body shown in FIG. 6B, the subcell formed on the right side and the subcell formed at the left side are electrically connected to each other.

After the formation of the conducting path 52, processes including precise etching for forming a device and formation of a contact pad are performed on the laminated body. In this case, the subcells are in electrical contact via the conducting path 52, whereby the etching uniformity is maintained.

The etching process is carried out before lines are formed in the subsequent process, and an unnecessary conducting path 53 between adjacent subcells (not shown) is removed as shown in FIG. 7A. Specifically, as shown in FIG. 7B, the etching process is carried out so as to reach the semi-insulating semiconductor substrate, and the conducting path 52 between the adjacent subcells is disrupted, whereby complete isolation between the formed devices is achieved.

As described above, in Prior Art disclosed in Japanese Unexamined Patent Application Publication No. 10-163223, all the elements are connected via the conducting path 52 during the etching process, and the conducting path 53 between the elements, which are not intended to be connected, is removed by the etching process before the formation of lines in the subsequent process, thereby achieving isolation between the elements.

### SUMMARY

The present inventors have found a problem that in Prior Art disclosed in Japanese Unexamined Patent Application Publication No. 10-163223, in order to achieve the isolation between the elements, which are not intended to be connected, it is necessary to additionally perform the etching process for disrupting the unnecessary conducting path 53, which results in an increase in the number of manufacturing processes. Accordingly, the number of etching masks for forming the integrated circuit is increased. Furthermore, the additional etching process causes a problem of an increase in price and the number of processes, for example.

A first exemplary aspect of the present invention is a method of manufacturing a semiconductor device including an integrated circuit having a plurality of semiconductor elements which are formed on a semiconductor substrate and electrically connected through a line, the method including: forming a conducting path to be connected to the semiconductor elements in a similar manner as the line is to be connected thereto; etching the semiconductor elements in a state where the semiconductor elements are electrically connected via the conducting path; and forming the line to be connected to the semiconductor elements in a similar manner as the conducting path is connected thereto.

With this method, the conducting path which is formed to achieve uniform etching can be finally short-circuited by the line. Further, no unnecessary conducting path exists after the formation of the line, thereby preventing an increase in the number of manufacturing processes.

According to an exemplary embodiment of the present invention, it is possible to provide a method of manufacturing a semiconductor device capable of forming a conducting path which has no influence on a circuit, without increasing the number of processes and masks, and capable of precise etching.

### BRIEF DESCRIPTION OF THE DRAWINGS

The above and other objects, advantages and features of the present invention will be more apparent from the following description of certain exemplary embodiments taken in conjunction with the accompanying drawings, in which:

FIG. 1 is a schematic diagram illustrating a method of manufacturing a semiconductor device according to an exemplary embodiment of the present invention;

FIG. 2 is a schematic diagram illustrating the method of manufacturing a semiconductor device according to an exemplary embodiment of the present invention;

FIG. 3 is a circuit diagram of a semiconductor device formed by using the manufacturing method according to an exemplary embodiment of the present invention;

FIG. 4 is a schematic diagram showing an example of a semiconductor device formed by using a conventional method of manufacturing a semiconductor device;

FIG. 5 is a circuit diagram of the semiconductor device shown in FIG. 4;

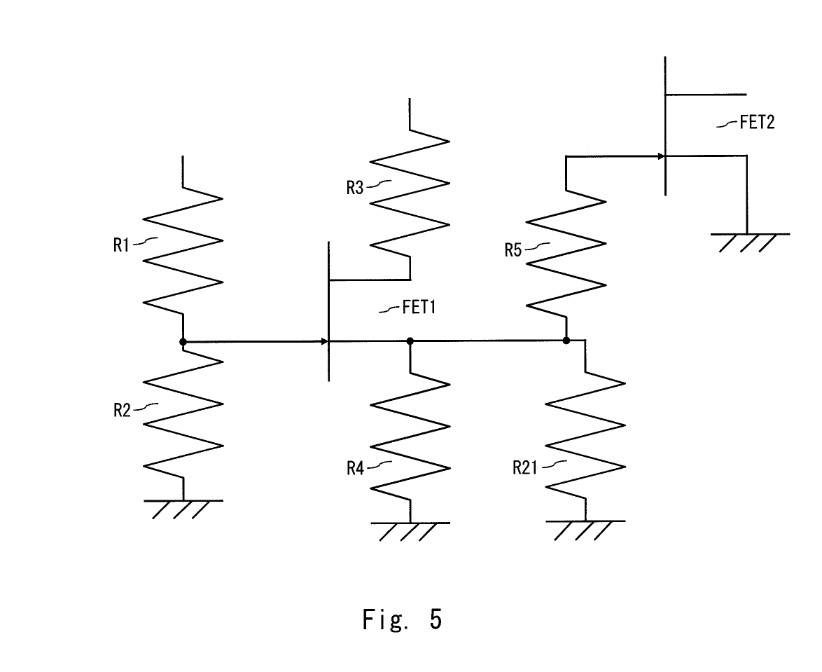

FIGS. 6A and 6B are diagrams each illustrating a method of manufacturing a semiconductor device according to Prior Art; and

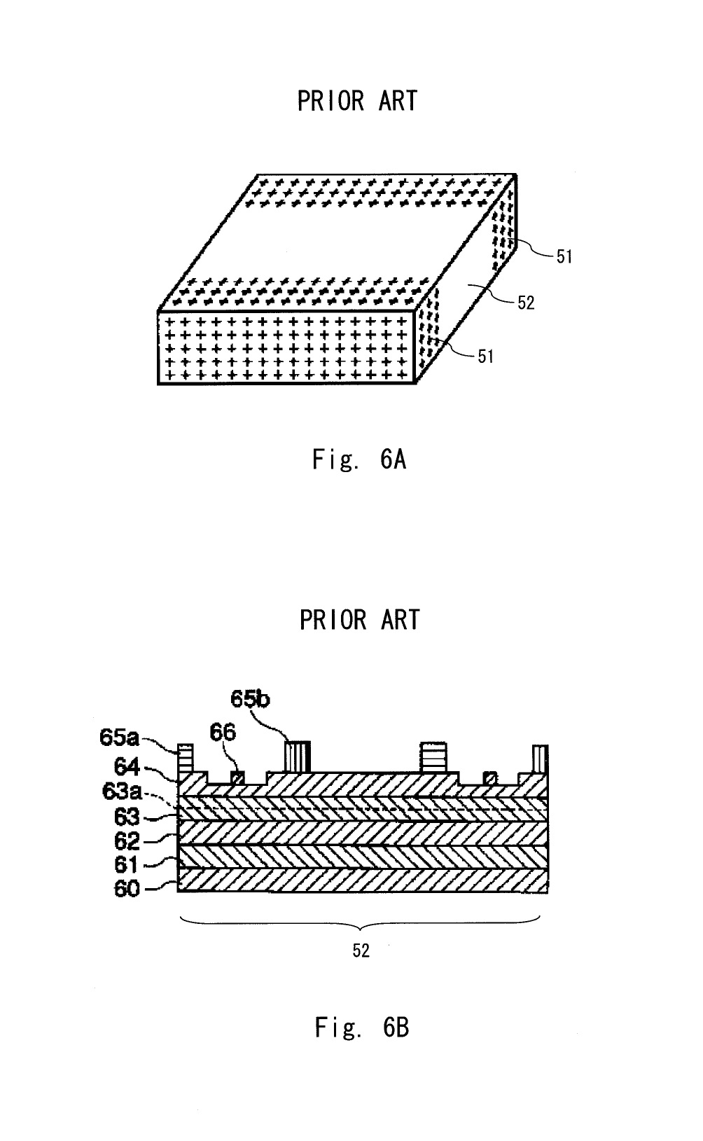

FIGS. 7A and 7B are diagrams each illustrating a method of manufacturing a semiconductor device according to Prior Art.

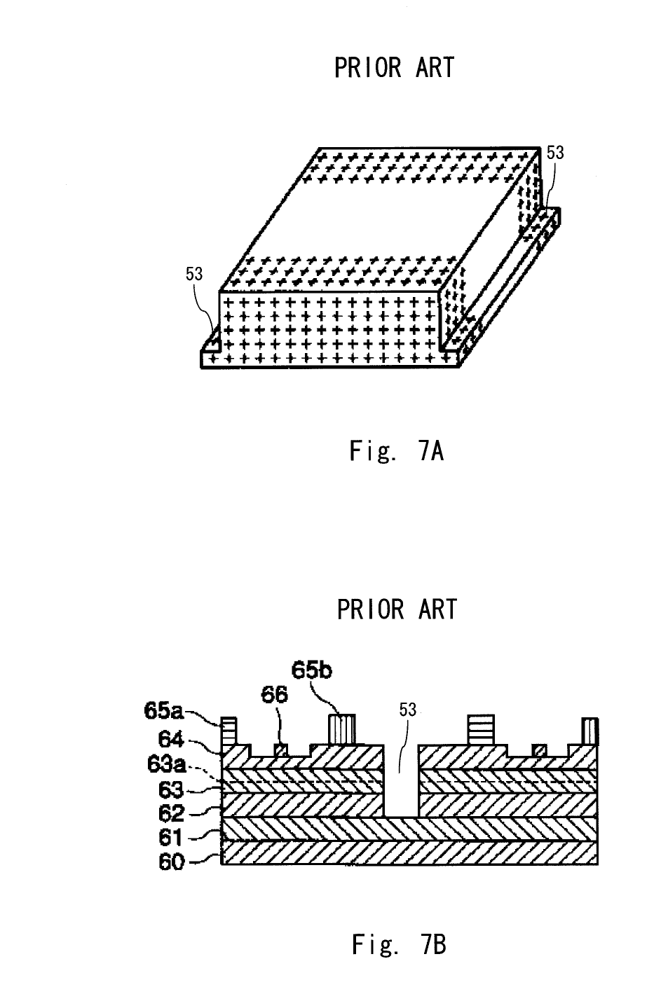

### DETAILED DESCRIPTION OF THE EXEMPLARY EMBODIMENTS

Preferred exemplary embodiments of the present invention will be described below. The following description of exemplary embodiments of the present invention is illustrative only, and the present invention is not limited to the exemplary embodiments described below. To clarify the explanation, omissions and simplifications are made as necessary in the following description and the drawings. Additionally, a redundant description thereof is omitted as appropriate for clarification of the explanation. Note that like components are denoted by like reference symbols in the drawings, and a description thereof is omitted as appropriate.

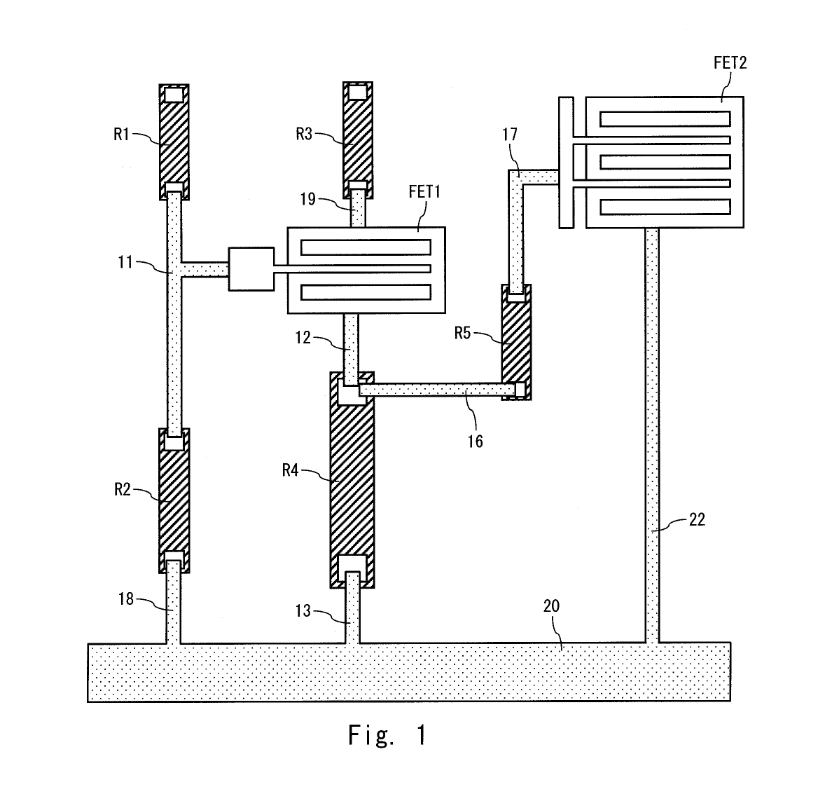

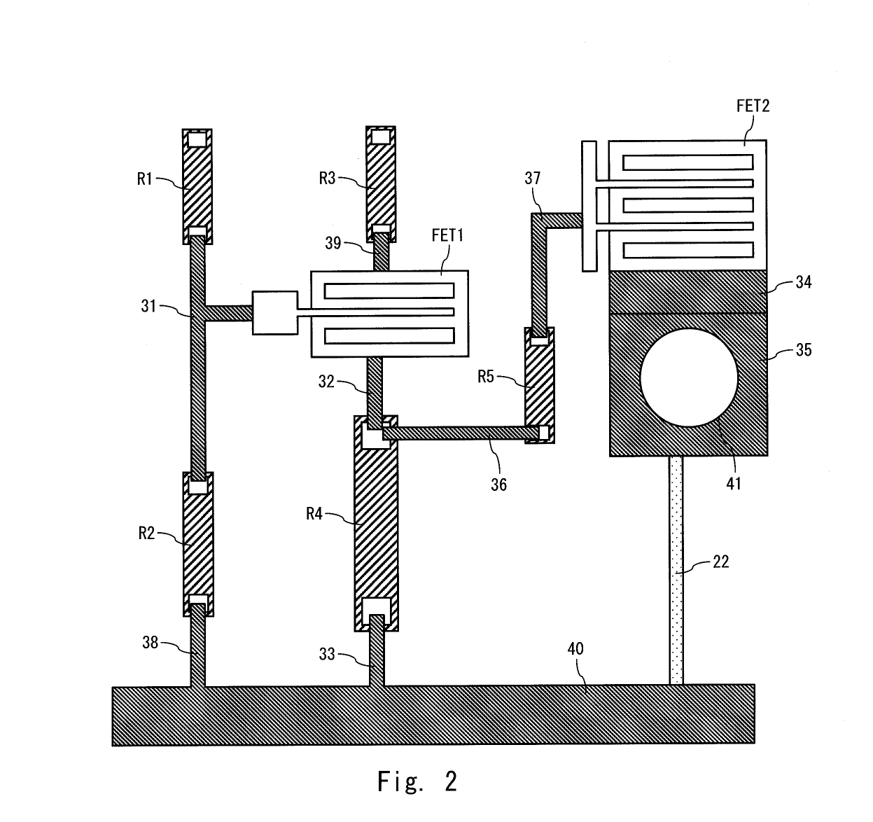

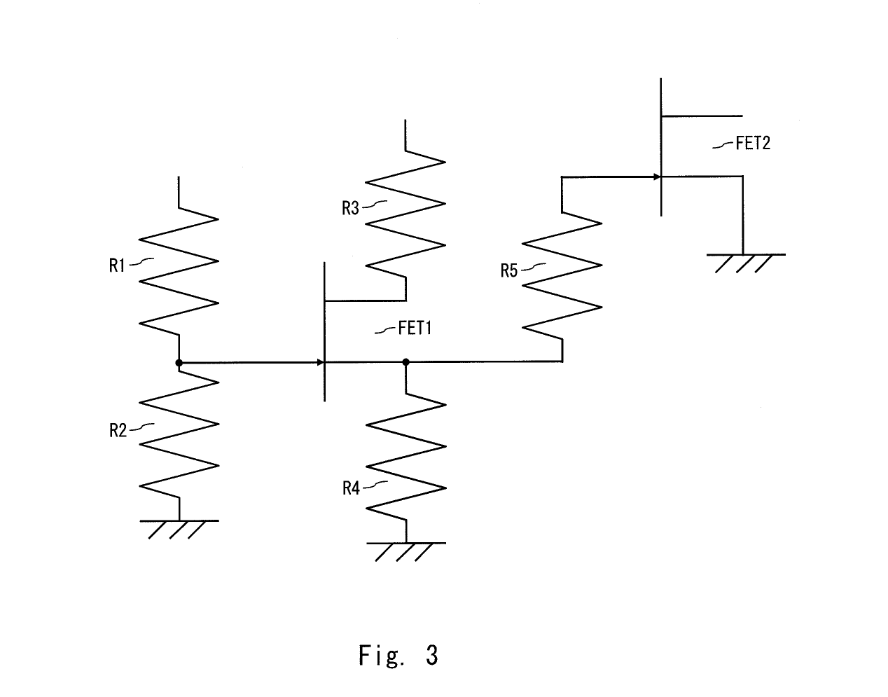

A method of manufacturing a semiconductor device according to an exemplary embodiment of the present invention will be described with reference to FIGS. 1 to 3. FIGS. 1 and 2 are schematic diagrams each illustrating the method of manufacturing a semiconductor device according to this exemplary embodiment. FIG. 3 is a circuit diagram of the semiconductor device formed by using the manufacturing method according to this exemplary embodiment. FIG. 1 is a schematic diagram illustrating an etching process, and FIG. 2 is a schematic diagram illustrating a line forming process. This exemplary embodiment is applied to a method of manufacturing a semiconductor device including an integrated circuit in which a plurality of semiconductor elements formed on a semiconductor substrate are electrically connected via a line. Hereinafter, a description is given of an example in which this exemplary embodiment is applied to the case of manufacturing a semiconductor device including an integrated circuit having a transistor whose terminal is not directly connected to a ground plane.

In this case, a description is given of a semiconductor device including an integrated circuit having an amplifying transistor FET2 whose source is grounded and a bias circuit for supplying a bias to the amplifying transistor FET2, as an example of the integrated circuit having a transistor whose terminal is not directly connected to the ground plane. Specifically, as shown in FIG. 3, the bias circuit has a configuration in which the gate of a bias transistor FET1 is connected between resistors R1 and R2 for supplying a bias to the bias transistor FET1. The bias transistor FET1 has a drain connected to a resistor R3 and a source connected to a resistor R4 for feedback control of the bias circuit. Further, the source of the bias transistor FET1 is connected to the gate of the amplifying transistor FET2 through a resistor R5. Note that each of the resistors R1 and R4 is grounded, and the source of the amplifying transistor FET2 is grounded via a through-hole.

A detailed description is given of the case of manufacturing the semiconductor device which includes the integrated circuit having the bias transistor FET1 whose source is grounded through the resistor R4, according to this exemplary embodiment.

Before the etching process requiring high precision is carried out, a semiconductor (diffusion line) having a conductivity is electrically connected to part of the semiconductor elements that are disposed independently of each other on the semiconductor substrate, thereby forming conducting paths. In this case, according to this exemplary embodiment, the conducting paths are connected to the semiconductor elements in a similar manner as in the circuit diagram of the semiconductor device to be manufactured. That is, the conducting paths are connected to the semiconductor elements in a similar manner as lines formed in a process described later are connected to the semiconductor elements. The conducting paths that are to be connected to transistors are formed from non-insulating regions.

In the case of the semiconductor device shown in FIG. 1, conducting paths 11, 12, 13, 16, 17, 18, 19, and 22 are formed to be connected to the bias transistor FET1, the amplifying transistor FET2, and the resistors R1 to R4, in accordance with the circuit diagram of FIG. 3.

Specifically, the conducting path 11 is formed so that one end of the resistor R1 is connected to one end of the resistor R2 and a node between the resistors R1 and R2 is connected to the non-insulating region in which the gate of the bias transistor FET1 is formed. The conducting path 19 is formed so that the non-insulating region in which the drain of the bias transistor FET1 is formed is connected to one end of the resistor R3. The conducting path 12 is formed so that the non-insulating region in which the source of the bias transistor FET1 is formed is connected to one end of the resistor R4. The conducting path 16 is formed to connect one end of the resistor R4 to which the conducting path 12 is connected and one end of the resistor R5.

The conducting path 17 is formed so that the other end of the resistor R5 is connected to the non-insulating region in which the gate of the amplifying transistor FET2 is formed. The conducting path 22 is formed to connect the non-insulating region in which the source of the amplifying transistor FET2 is formed and a conducting path ground plane 20. The conducting path 13 is formed so that the other end of the resistor R4 is connected to the conducting path ground plane 20. The conducting path 18 is formed so that the other end of the resistor R2 is connected to the conducting path ground plane 20.

Thus, all the semiconductor elements are electrically connected via the conducting paths. In this state, the etching process is carried out. All the elements are electrically connected via the conducting paths at this time, which allows electrons to move freely. As a result, each semiconductor element can be etched with high precision.

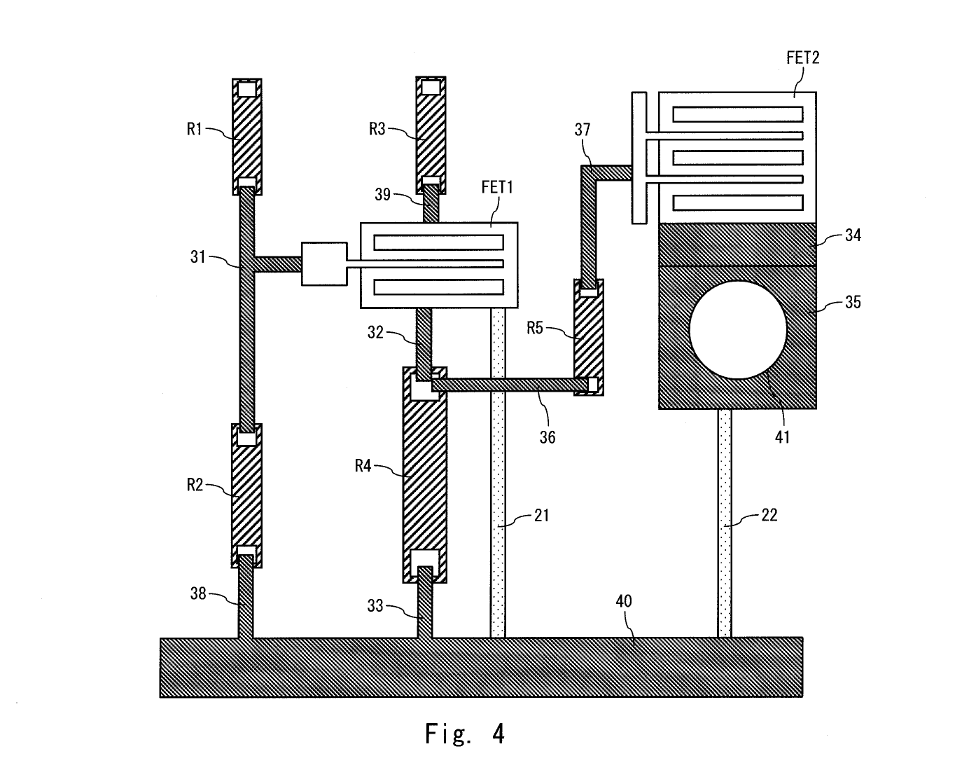

Particularly in this exemplary embodiment, the bias transistor FET1 is connected to the conducting path ground plane 20 via the conducting paths and the resistor, unlike the conventional method explained with FIG. 4. Further, the bias transistor FET1 and the amplifying transistor FET2 are connected via the conducting paths and resistors. As a result, the electrons generated in the etching process can move freely. Accordingly, uniform etching is achieved, and transistors having uniform characteristics can be obtained.

After the etching process is carried out, lines are formed in the subsequent process to connect the semiconductor elements to each other. In this case, according to this exemplary embodiment, the lines are connected to the semiconductor elements in a similar manner as in the circuit diagram of the semiconductor device to be manufactured. That is, the lines are connected to the semiconductor elements in a similar manner as the conducting paths, which are formed in the above-mentioned process, to the semiconductor elements. Accordingly, the lines are connected in parallel with the conducting paths. This is because the conducting paths are formed in advance to be connected to the semiconductor elements in a similar manner as in the circuit diagram of the semiconductor device to be manufactured, at the stage of formation of the conducting paths. Accordingly, when the lines are formed at the subsequent stage of forming the lines so as to be connected to the semiconductor elements in a similar manner as in the circuit diagram of the semiconductor device to be manufactured, the lines are arranged in parallel with the conducting paths. As a result, the conducting paths are short-circuited by the lines.

In the case of the semiconductor device shown in FIG. 2, lines 31 to 39 are formed to be connected to the bias transistor FET1, the amplifier transistor FET2, and the resistors R1 to R4, in accordance with the circuit diagram of FIG. 3.

Specifically, the line 31 is formed so that one end of the resistor R1 is connected to one end of the resistor R2 and a node between the resistors R1 and R2 is connected to the gate of the bias transistor FET1. This allows the conducting path 11 to be short-circuited by the line 31. The line 39 is formed so that the drain of the bias transistor FET1 is connected to one end of the resistor R3. This allows the conducting path 19 to be short-circuited by the line 39. The line 32 is formed so that the source of the bias transistor FET1 is connected to one end of the resistor R4. This allows the conducting path 12 to be short-circuited by the line 32. The line 36 is formed to connect one end of the resistor R4 to which the line 32 is connected and one end of the resistor R5. This allows the conducting path 16 to be short-circuited by the line 36.

Further, the line 37 is formed so that the other end of the resistor R5 is connected to the gate of the amplifying transistor FET2. This allows the conducting path 17 to be short-circuited by the line 37. The line 33 is formed so that the other end of the resistor R4 is connected to a ground plane 40. This allows the conducting path 13 to be short-circuited by the line 33. The line 38 is formed so that the other end of the resistor R2 is connected to the ground plane 40. This allows the conducting path 18 to be short-circuited by the line 38.

Note that the line 35 is formed to be connected to the source of the amplifying transistor FET2 through the line 34, and is grounded via a through-hole 41 which is formed in the line 35. In this case, the source of the amplifying transistor FET2 is grounded via the through-hole 41. Accordingly, even if the line extending from the source of the amplifying transistor FET2 to the ground plane 40 is not formed, the conducting path 22 connected to the conducting path ground plane 20 has no influence on the circuit. Therefore, in this case, it is not necessary to form the line connected in parallel with the conducting path 22 which is connected to the conducting path ground plane 20, i.e., the line connected to the ground plane 40.

The circuit diagram of the semiconductor device thus manufactured is the same as the diagram of the circuit originally designed, as shown in FIG. 3. Unlike the conventional method explained with FIG. 4, the conducting paths that are formed to achieve uniform etching are finally short-circuited by the lines in this exemplary embodiment, resulting in no influence on the final form of the circuit. Moreover, unlike Prior Art disclosed in Japanese Unexamined Patent Application Publication No. 10-163223, the conducting path that becomes unnecessary after the line forming process does not exist in this exemplary embodiment. Accordingly, there is no need to provide an additional process for removing the conducting path. As a result, in manufacturing various FET circuits, HBT circuits, HET circuits and the like, the conducting paths having no influence on the circuit can be arranged without increasing the number of processes and masks, and precise etching can be achieved.

As described above, in this exemplary embodiment, the conducting paths are formed to be connected to the semiconductor elements in a similar manner as in the circuit diagram of the semiconductor device to be manufactured, and the etching process is carried out in the state where the semiconductor elements are electrically connected via the conducting paths. After the etching process, the lines are formed to be connected to the semiconductor elements in a similar manner as in the circuit diagram of the semiconductor device to be manufactured. With this method, the conducting paths formed to achieve uniform etching are finally short-circuited by the lines. Accordingly, the conducting paths have no influence on the final form of the circuit. Further, the conducting path that becomes unnecessary after the line forming process does not exist. Accordingly, there is no need to provide an additional process for removing the conducting path. As a result, the conducting paths having no influence on the circuit can be arranged without increasing the number of processes and masks, and precise etching can be achieved. In other words, uniform etching can be achieved irrespective of the final circuit configuration, and this exemplary embodiment can be applied to various FET circuits, HBT circuits, and HET circuits without increasing the number of manufacturing processes.

Particularly in this exemplary embodiment, even in the case of manufacturing the semiconductor device which includes an integrated circuit having a transistor whose terminal is not directly connected to the ground plane, conducting paths having no influence on the final circuit configuration can be formed, and precise etching can be achieved. Therefore, unlike the conventional method which is explained with FIG. 4 and can be applied only to particular circuits, this exemplary embodiment can be applied to any circuit configuration. Thus, this exemplary embodiment can also be suitably applied to the case of manufacturing the semiconductor device which includes an integrated circuit having a transistor whose terminal is not directly connected to the ground plane.

Though all the semiconductor elements to be etched are electrically connected via the conducting paths in the above exemplary embodiment, it is not necessary to electrically connect all the semiconductor elements. For example, when the etching uniformity is deteriorated, the characteristics of transistors are most susceptible to the deterioration of the etching uniformity, among the semiconductor elements, while the deterioration of the etching uniformity may have no influence on the characteristics of resistors. In this case, precise etching may be performed on at least the transistors. That is, etching may be performed in the state where at least elements requiring precise etching are electrically connected to each other and part of the elements electrically connected together are grounded.

Specifically, in the semiconductor device shown in FIG. 1, at least the following conducting paths may be formed: the conducting path 12 for connecting the non-insulating region of the bias transistor FET1 to one end of the resistor R4; the conducting path 16 for connecting one end of the resistor R4 to which the conducting path 12 is connected and one end of the resistor R5; the conducting path 17 for connecting the other end of the resistor R5 to the non-insulating region of the amplifying transistor FET2; and the conducting path 22 for connecting the non-insulating region of the amplifying transistor FET2 to the conducting path ground plane 20.

Alternatively, at least the following conducting paths are formed: the conducting path 12 for connecting the non-insulating region of the bias transistor FET1 to one end of the resistor R4; the conducting path 16 for connecting one end of the resistor R4 to which the conducting path 12 is connected and one end of the resistor R5; the conducting path 17 for connecting the other end of the resistor R5 to the non-insulating region of the amplifying transistor FET2; and the conducting path 13 for connecting the other end of the resistor R4 to the conducting path ground plane 20.

In this manner, etching may be carried out in the state where the bias transistor FET1 and the amplifying transistor FET2 are electrically connected via the conducting paths and resistors and are electrically connected to the conducting path ground plane 20. As a result, at least the bias transistor FET1 and the amplifying transistor FET2 can be etched with high precision. Also in this case, the conducting paths which are formed to achieve uniform etching are finally short-circuited by the lines formed in the subsequent process, and therefore, the conducting paths have no influence on the final form of the circuit. Consequently, the conducting paths having no influence on the circuit can be arranged without increasing the number of processes and masks, and precise etching can be achieved.

The above exemplary embodiments are illustrative only, and the present invention is not limited to the above exemplary embodiments. Moreover, it will be understood by those skilled in the art that modifications, additions, and changes can be easily made to the elements of the above exemplary embodiment without departing from the scope of the present invention.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A method of manufacturing a semiconductor device comprising an integrated circuit including a plurality of semiconductor elements formed on a semiconductor substrate and electrically connected through a line, the method comprising:
forming a conducting path to be connected to the semiconductor elements in a similar manner as the line is to be connected thereto;
etching the semiconductor elements in a state where the semiconductor elements are electrically connected via the conducting path; and
forming the line to be connected to the semiconductor elements in a similar manner as the conducting path is connected thereto.

2. The method of manufacturing a semiconductor device according to claim 1, wherein the formation of the line allows the conducting path to be short-circuited by the line.

3. The method of manufacturing a semiconductor device according to claim 1, wherein the conducting path is formed so that at least semiconductor elements requiring precise etching, among the plurality of semiconductor elements, are electrically connected to each other.

4. The method of manufacturing a semiconductor device according to claim 1, wherein the conducting path is formed so that the semiconductor elements electrically connected via the conducting path are electrically connected to a ground plane.

5. The method of manufacturing a semiconductor device according to claim 1, wherein the integrated circuit includes a transistor and a resistor as the semiconductor elements.

6. The method of manufacturing a semiconductor device according to claim 5, wherein the integrated circuit includes the transistor having a terminal not directly connected to a ground plane.
